(19) United States
(12) Patent Application Publication
(10) Pub. No.: US 2024/0364199 A1
(43) Pub. Date: Oct. 31, 2024

(54) SMOOTHING OF FILTER RESPONSE IN A CLOSED-LOOP SYSTEM

(71) Applicant: Cirrus Logic International Semiconductor Ltd., Edinburgh (GB)

(72) Inventors: Hasnain AKRAM, Austin, TX (US); Graeme G. MACKAY, Austin, TX (US)

(73) Assignee: Cirrus Logic International Semiconductor Ltd., Edinburgh (GB)

(21) Appl. No.: 18/308,938

(22) Filed: Apr. 28, 2023

(51) Int. Cl. H02M 1/00; H02M 3/158; H03H 7/01

(52) U.S. Cl. CPC H02M 1/0003; H02M 3/158; H03H 7/0153

(57) ABSTRACT

A system may include a first closed-loop feedback control loop, comprising a first filter located within a signal path of the first closed-loop feedback control loop and configured to regulate a physical quantity comprising at least one of an output voltage or an output current of the system and a second filter communicatively coupled to the first filter and configured to, based on one or more variables associated with the closed-loop feedback control system, control at least one filter parameter of the first filter in order to control a response of the first filter. The system may also include a second closed-loop feedback system nested with the first closed-loop feedback control loop comprising a power converter comprising a plurality of switches and a power inductor and a loop filter configured to control an inductor current through the power inductor.

### FIELD OF DISCLOSURE

The instant disclosure relates generally to processing systems, and more specifically, to systems and methods for smoothing a filter response in a closed-loop system.

### BACKGROUND

Closed-loop feedback control systems are ubiquitous in many applications, including audio processing, regulation of physical quantities (e.g., temperatures, voltages), and many other uses. FIG. 1 illustrates selected components of an example closed-loop feedback system 1 for regulating a physical quantity OUT based on a setpoint quantity REF, as is known in the art. As shown in FIG. 1, system 1 may include a combiner 2 for generating an error signal ERROR based on a difference between setpoint quantity REF and a filtered version OUT′ of physical quantity OUT. A loop filter 4 may operate on error signal ERROR in order to generate a control signal for controlling a plant 6 that generates physical quantity OUT. For example, loop filter 4 may apply a variable response to error signal ERROR in order to provide one or more of proportional control, integral control, and derivative control in order to regulate physical quantity OUT. Plant 6 may include any system, device, or apparatus configured to generate physical quantity OUT under the control of the control signal generated by loop filter 4 in order to regulate physical quantity OUT. Non-limiting examples of plant 6 may include an electronic amplifier that generates a signal voltage as physical quantity OUT, an inductive power converter that regulates a current or voltage as physical quantity OUT, a motor servo system that sets a position of a mechanical feature as physical quantity OUT, or a heating/cooling system that generates a temperature as physical quantity OUT. As shown in FIG. 1, closed-loop feedback system 1 may also include a feedback filter 8 that applies feedback response to physical quantity OUT in order to generate filtered physical quantity OUT′, although in some embodiments, feedback filter 8 may not be present, in which case OUT′=OUT.

In closed-loop feedback system 1, loop filter 4 may have a variable response (e.g., a variable proportional gain and/or other variable response parameters) that may vary instantaneously as a function of system parameters, such as a magnitude of error signal ERROR, for example. Such variable response may assist, for example, in achieving fast transient bandwidth while maintaining stead-state noise and/or stability. In certain corner conditions, such as when the system bandwidth is pushed high, changes in error signal ERROR may alter a response of loop filter 4, which in turn may further alter error signal ERROR, potentially creating undesirable oscillation/chatter in error signal ERROR and ultimately undesirable oscillation/chatter in physical quantity OUT.

### SUMMARY

In accordance with the teachings of the present disclosure, certain disadvantages and problems associated with existing closed-loop feedback control systems may be reduced or eliminated.

In accordance with embodiments of the present disclosure, a system may include a first closed-loop feedback control loop, comprising a first filter located within a signal path of the first closed-loop feedback control loop and configured to regulate a physical quantity comprising at least one of an output voltage or an output current of the system and a second filter communicatively coupled to the first filter and configured to, based on one or more variables associated with the closed-loop feedback control system, control at least one filter parameter of the first filter in order to control a response of the first filter. The system may also include a second closed-loop feedback system nested with the first closed-loop feedback control loop comprising a power converter comprising a plurality of switches and a power inductor and a loop filter configured to control an inductor current through the power inductor.

In accordance with embodiments of the present disclosure, a method may be provided in a system having a first closed-loop feedback control loop and a second closed-loop feedback system nested with the first closed-loop feedback control loop wherein the first closed-loop feedback control loop includes a first filter located within a signal path of the first closed-loop feedback control loop and configured to regulate a physical quantity comprising at least one of an output voltage or an output current of the system and the second closed-loop feedback system includes a power converter comprising a plurality of switches and a power inductor a loop filter configured to control an inductor current through the power inductor. The method may include controlling, with a second filter communicatively coupled to the first filter and configured to, based on one or more variables associated with the closed-loop feedback control system, at least one filter parameter of the first filter in order to control a response of the first filter.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example closed-loop feedback control system, as is known in the art;

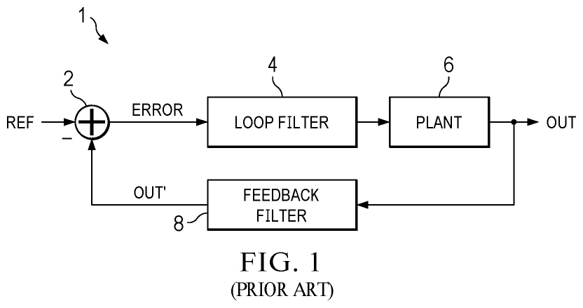

FIG. 2 illustrates a block diagram of selected components of an example closed-loop feedback control system, in accordance with embodiments of the present disclosure;

FIG. 3 illustrates a block diagram of selected components of the closed-loop feedback control system of FIG. 2 with control of a loop filter based on a loop error signal, in accordance with embodiments of the present disclosure; and

FIG. 4 illustrates a block diagram of selected components of an example closed-loop feedback control system with a plant of the system comprising an inductive power converter, in accordance with embodiments of the present disclosure.

### DETAILED DESCRIPTION

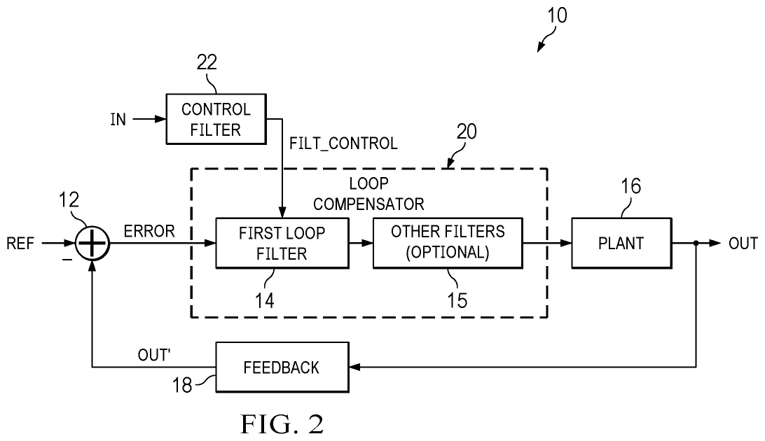

FIG. 2 illustrates a block diagram of selected components of an example closed-loop feedback control system 10 for regulating a physical quantity OUT based on a setpoint quantity REF, in accordance with embodiments of the present disclosure. As shown in FIG. 2, system 10 may include a combiner 12 for generating an error signal ERROR based on a difference between setpoint quantity REF and a filtered version OUT′ of physical quantity OUT. A loop compensator 20, which may include a first loop filter 14 and one or more other filters 15, may operate on error signal ERROR in order to generate a control signal for controlling a plant 16 that generates physical quantity OUT. For example, first loop filter 14 may apply a variable response to error signal ERROR in order to provide one or more of proportional control, integral control, and derivative control in order to regulate physical quantity OUT. Plant 16 may include any system, device, or apparatus configured to generate physical quantity OUT under the control of the control signal generated by loop compensator 20 in order to regulate physical quantity OUT. Non-limiting examples of plant 16 may include an electronic amplifier that generates a signal voltage as physical quantity OUT, an inductive power converter that regulates a current or voltage as physical quantity OUT, a motor servo system that sets a position of a mechanical feature as physical quantity OUT, or a heating/cooling system that generates a temperature as physical quantity OUT. As shown in FIG. 2, closed-loop feedback system 10 may also include a feedback filter 18 that applies feedback response to physical quantity OUT in order to generate filtered physical quantity OUT′, although in some embodiments, feedback filter 18 may not be present, in which case OUT′=OUT.

As also shown in FIG. 2, system 10 may include a control filter 22 configured to, based on one or more input variable(s) IN, generate a control signal FILT_CONTROL configured to control parameters (e.g., filter coefficients, including without limitation filter coefficients that may affect a filter gain and/or filter bandwidth) of first loop filter 14 in order to smooth the response of first loop filter 14 as a function of input variable(s) IN. Control filter 22 may comprise a low-pass filter, bandpass filter, high-pass filter, or any other suitable linear or nonlinear filter for providing desired smoothing of the response first loop filter 14. Thus, control filter 22 may dynamically control the response of first loop filter 14 based on input variable(s) IN. In some instances, smoothing of the response of first loop filter 14 may aid in smoothing the response of the overall feedback and reduce undesired oscillation/chatter.

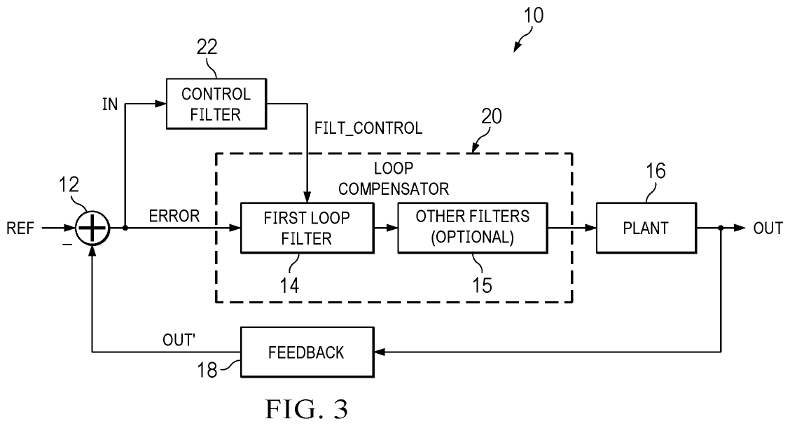

The one or more input variable(s) IN may include any appropriate variables from which control filter 22 may generate control signal FILT_CONTROL for controlling parameters of first loop filter 14. For instance, as shown in FIG. 3, in some embodiments of closed-loop feedback system 10, the one or more variable(s) IN may include error signal ERR.

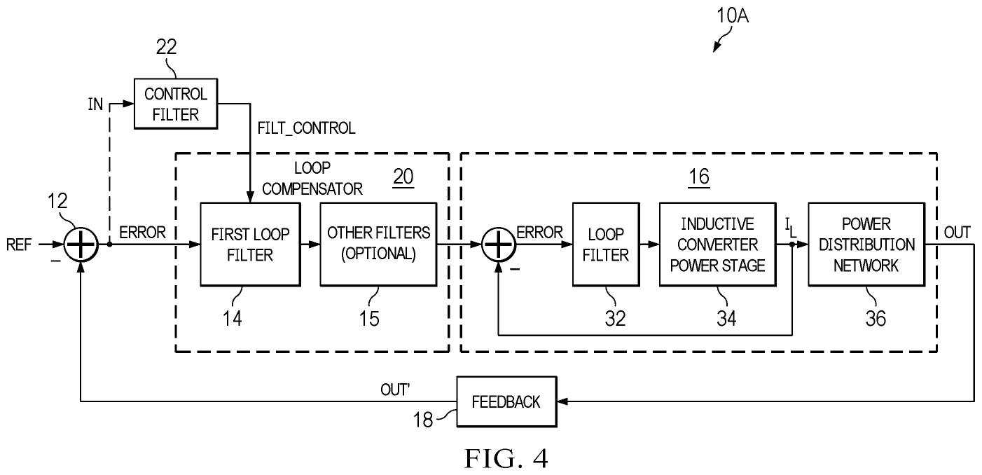

FIG. 4 illustrates a block diagram of selected components of an example closed-loop feedback control system 10A with plant 16 of the closed-loop feedback control system 10A comprising an inductive power converter, in accordance with embodiments of the present disclosure. Closed-loop feedback control system 10A may be similar in many respects to closed-loop feedback control systems 10 shown in FIGS. 2 and 3, but with plant 16 implemented with a loop filter 32, inductive converter power stage 34 (which may also be referred to as a switched mode power supply), and a power distribution network 36 as shown in FIG. 4. In FIG. 4, the output of loop compensator 20 may define a target for an inductor current I_{L} driven by inductive power converter power stage I_{L}. Loop filter 32 may apply a response to an embedded error signal ERR equal to a difference between the target for inductor current I_{L} and actual inductor current I_{L} in order to provide one or more of proportional control, integral control, and derivative control in order to regulate inductor current I_{L}, which in turn may regulate physical quantity OUT. In the embodiments represented by FIG. 4, physical quantity OUT may comprise a voltage or a current.

Loop filter 32 may output one or more control switches of inductive converter power stage 34 to control inductor current I_{L} flowing through a power inductor of inductive converter power stage 34. Inductive converter power stage 34 may comprise a boost converter, buck converter, buck-boost converter, or any other suitable type of power converter. Power distribution network 36 may comprise any suitable network of electronic components that may be driven or regulated from inductor current I_{L}.

The operations described above may be performed by a processor or any other circuit configured to perform the described operations. Such a circuit may be an integrated circuit (IC) constructed on a semiconductor substrate and include logic circuitry, such as transistors configured as logic gates, and memory circuitry, such as transistors and capacitors configured as dynamic random access memory (DRAM), electronically programmable read-only memory (EPROM), or other memory devices. The logic circuitry may be configured through hard-wire connections or through programming by instructions contained in firmware. Further, the logic circuitry may be configured as a general-purpose processor (e.g., CPU or DSP) capable of executing instructions contained in software. The firmware and/or software may include instructions that cause the processing of signals described herein to be performed. The circuitry or software may be organized as blocks that are configured to perform specific functions. Alternatively, some circuitry or software may be organized as shared blocks that can perform several of the described operations. In some embodiments, the IC that is the controller may include other functionality. For example, the controller IC may include an audio coder/decoder (CODEC) along with circuitry for performing the functions described herein. Such an IC is one example of an audio controller. Other audio functionality may be additionally or alternatively integrated with the IC circuitry described herein to form an audio controller.

If implemented in firmware and/or software, functions described above may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically-erasable programmable read-only memory (EEPROM), compact disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks, and Blu-ray discs. Generally, disks reproduce data magnetically, and discs reproduce data optically. Combinations of the above should also be included within the scope of computer-readable media.

In addition to storage on computer readable media, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. For example, where general purpose processors are described as implementing certain processing steps, the general purpose processor may be a digital signal processor (DSP), a graphics processing unit (GPU), a central processing unit (CPU), or other configurable logic circuitry. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

The circuitry described above with reference to the accompanying drawings may be incorporated in a host device, preferably a battery-powered host device, such as a laptop, notebook, netbook or tablet computer, a gaming device such as a games console or a controller for a games console, a virtual reality (VR) or augmented reality (AR) device, a mobile telephone, a portable audio player or some other portable device, a power tool or other handheld electronic device, a wearable device such as a wearable health monitor, or may be incorporated in an accessory device for use with a laptop, notebook, netbook or tablet computer, a gaming device, a VR or AR device, a mobile telephone, a portable audio player or other portable device. The described circuitry may be incorporated into a vehicle or other automotive product.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
a first closed-loop feedback control loop, comprising:
a first filter located within a signal path of the first closed-loop feedback control loop and configured to regulate a physical quantity comprising at least one of an output voltage or an output current of the system; and
a second filter communicatively coupled to the first filter and configured to, based on one or more variables associated with the closed-loop feedback control system, control at least one filter parameter of the first filter in order to control a response of the first filter; and
a second closed-loop feedback system nested with the first closed-loop feedback control loop comprising:
a power converter comprising a plurality of switches and a power inductor; and
a loop filter configured to control an inductor current through the power inductor.

2. The system of claim 1, wherein the one or more variables comprise a signal error between the physical quantity regulated by the closed-loop feedback control loop and a setpoint reference for the physical quantity.

3. The system of claim 1, wherein the at least one filter parameter comprises a gain of the first filter.

4. The system of claim 1, wherein the at least one filter parameter comprises a bandwidth of the first filter.

5. The system of claim 1, wherein the at least one filter parameter comprises at least one filter coefficient of the first filter.

6. The system of claim 1, wherein the second filter comprises a low-pass filter.

7. The system of claim 1, wherein the second filter comprises a high-pass filter.

8. The system of claim 1, wherein the second filter comprises a band-pass filter.

9. The system of claim 1, wherein the second filter comprises a linear filter.

10. The system of claim 1, wherein the second filter comprises a non-linear filter.

11. A method, in a system having a first closed-loop feedback control loop and a second closed-loop feedback system nested with the first closed-loop feedback control loop wherein the first closed-loop feedback control loop includes a first filter located within a signal path of the first closed-loop feedback control loop and configured to regulate a physical quantity comprising at least one of an output voltage or an output current of the system and the second closed-loop feedback system includes a power converter comprising a plurality of switches and a power inductor a loop filter configured to control an inductor current through the power inductor, the method comprising:
controlling, with a second filter communicatively coupled to the first filter and configured to, based on one or more variables associated with the closed-loop feedback control system, at least one filter parameter of the first filter in order to control a response of the first filter.

12. The method of claim 11, wherein the one or more variables comprise a signal error between the physical quantity regulated by the closed-loop feedback control loop and a setpoint reference for the physical quantity.

13. The method of claim 11, wherein the at least one filter parameter comprises a gain of the first filter.

14. The method of claim 11, wherein the at least one filter parameter comprises a bandwidth of the first filter.

15. The method of claim 11, wherein the at least one filter parameter comprises at least one filter coefficient of the first filter.

16. The method of claim 11, wherein the second filter comprises a low-pass filter.

17. The method of claim 11, wherein the second filter comprises a high-pass filter.

18. The method of claim 11, wherein the second filter comprises a band-pass filter.

19. The method of claim 11, wherein the second filter comprises a linear filter.

20. The method of claim 11, wherein the second filter comprises a non-linear filter.
